(19) United States
(12) Patent Application Publication
(10) Pub. No.: US 2025/0294823 A1
(43) Pub. Date: Sep. 18, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Katsuhisa TANAKA, Himeji Hyogo (JP); Hiroshi KONO, Himeji Hyogo (JP)

(21) Appl. No.: 19/227,404

(22) Filed: Jun. 3, 2025

Related U.S. Application Data
(63) Continuation of application No. PCT/JP2024/003665, filed on Feb. 5, 2024.

(30) Foreign Application Priority Data
Aug. 22, 2023 (JP) 2023-134761

(51) Int. Cl. H10D 62/10; H10D 30/01; H10D 30/66; H10D 62/13; H10D 62/17; H10D 62/60; H10D 62/832; H10D 64/27

(52) U.S. Cl. CPC H10D 62/105; H10D 30/0291; H10D 30/66; H10D 62/153; H10D 62/154; H10D 62/177; H10D 62/60; H10D 62/8325; H10D 64/512; H10D 64/514

(57) ABSTRACT

According to one embodiment, a semiconductor device includes first to third electrodes, a semiconductor layer, and a gate electrode. The semiconductor layer contains silicon carbide. The semiconductor layer includes first to third semiconductor regions. The gate electrode faces the second semiconductor region via a gate insulating layer. The gate electrode includes a first portion, a second portion, and a third portion. The first portion further faces the third semiconductor region. The second portion is positioned at an end of the gate electrode in a third direction. The third direction is perpendicular to the first direction and the second direction. The third portion is positioned between the first portion and the second portion in the third direction. The impurity concentration of the second portion is less than that of the third portion. The third electrode includes a wiring portion provided on the third portion.

### CROSS-REFERENCE TO RELATED APPLICATIONS

This is a continuation application of International Patent Application PCT/JP2024/003665, filed on Feb. 5, 2024. This application also claims priority to Japanese Patent Application No. 2023-134761, filed on Aug. 22, 2023. The entire contents of which are incorporated herein by reference.

### FIELD

Embodiments of the present invention generally relate to semiconductor devices.

### BACKGROUND

There are semiconductor devices using silicon carbide. There is a need for a technology that can suppress the occurrence of breakdown in semiconductor devices.

### BRIEF DESCRIPTION OF THE DRAWINGS

FIG. 1 is a plan view illustrating a semiconductor device according to an embodiment;

FIG. 2 is an enlarged plan view of part II of FIG. 1;

FIG. 3 is a III-III cross-sectional view of FIG. 2;

FIG. 4 is a IV-IV cross-sectional view of FIG. 2;

FIG. 5 is a V-V cross-sectional view of FIG. 2;

FIGS. 6A and 6B are cross-sectional views illustrating a manufacturing method for the semiconductor device according to the embodiment;

FIGS. 7A and 7B are cross-sectional views illustrating the manufacturing method for the semiconductor device according to the embodiment;

FIGS. 8A and 8B are cross-sectional views illustrating the manufacturing method for the semiconductor device according to the embodiment;

FIGS. 9A and 9B are cross-sectional views illustrating the manufacturing method for the semiconductor device according to the embodiment;

FIGS. 10A and 10B are plan views illustrating a second portion of a gate electrode;

FIG. 11 is a plan view illustrating a part of a semiconductor device according to a first modification of the embodiment;

FIG. 12 is a XII-XII cross-sectional view of FIG. 11

FIG. 13 is a plan view illustrating a part of a semiconductor device according to a second modification of the embodiment; and

FIG. 14 is a XIV-XIV cross-sectional view of FIG. 13.

### DETAILED DESCRIPTION

According to one embodiment, a semiconductor device includes a first electrode, a semiconductor layer, a second electrode, a gate electrode, and a third electrode. The semiconductor layer contains silicon carbide. The semiconductor layer includes a first semiconductor region of a first conductivity type, a second semiconductor region of a second conductivity type, and a third semiconductor region of the first conductivity type. The first semiconductor region is provided on the first electrode. The second semiconductor region is provided on the first semiconductor region. The third semiconductor region is provided on the second semiconductor region. The second electrode is provided on the second semiconductor region and the third semiconductor region. The gate electrode faces the second semiconductor region via a gate insulating layer in a second direction. The second direction is perpendicular to a first direction from the first electrode toward the first semiconductor region. The gate electrode includes a first portion, a second portion, and a third portion. The first portion further faces the third semiconductor region. The second portion is positioned at an end of the gate electrode in a third direction. The third direction is perpendicular to the first direction and the second direction. The third portion is positioned between the first portion and the second portion in the third direction. The impurity concentration of the second portion is less than the impurity concentration of the third portion. The third electrode is separated from the second electrode and electrically connected to the gate electrode. The third electrode includes a wiring portion provided on the third portion.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following descriptions and drawings, notations of n⁺, n⁻⁻ and p⁺, p, p⁻ represent relative levels of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. The notation with “−−” shows a relatively lower impurity concentration than the impurity concentration for the notation with “−”. These notations represent relative levels of net impurity concentrations after the mutual compensation of these impurities when respective regions include both of a p-type impurity and an n-type impurity. The embodiments described below may be implemented by reversing the p-type and the n-type of the semiconductor regions.

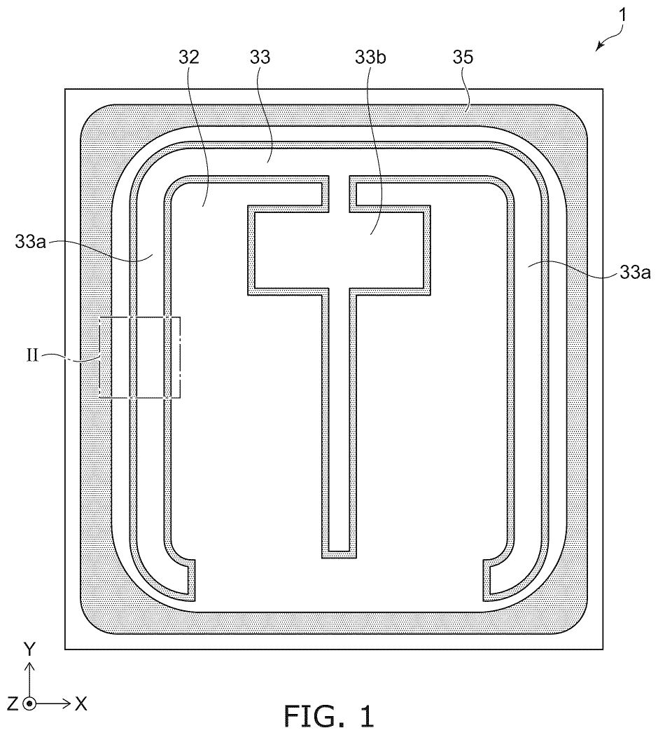

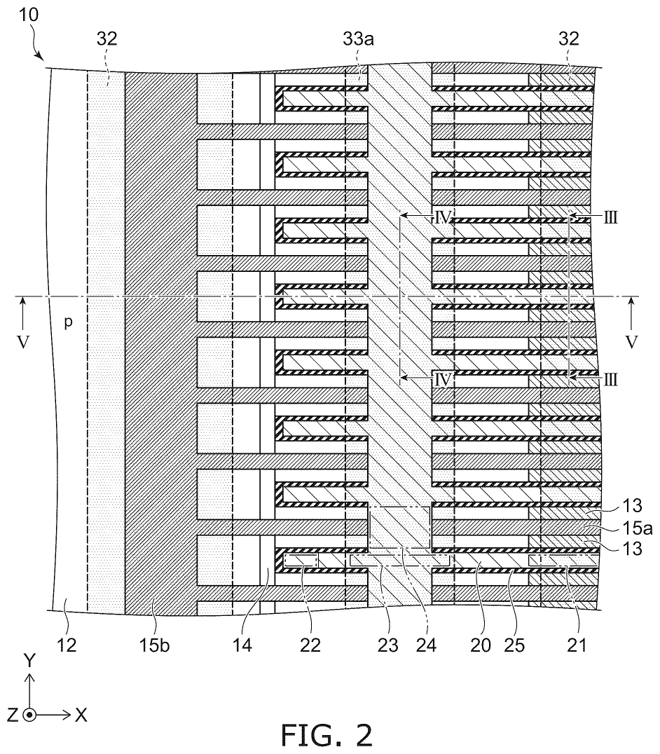

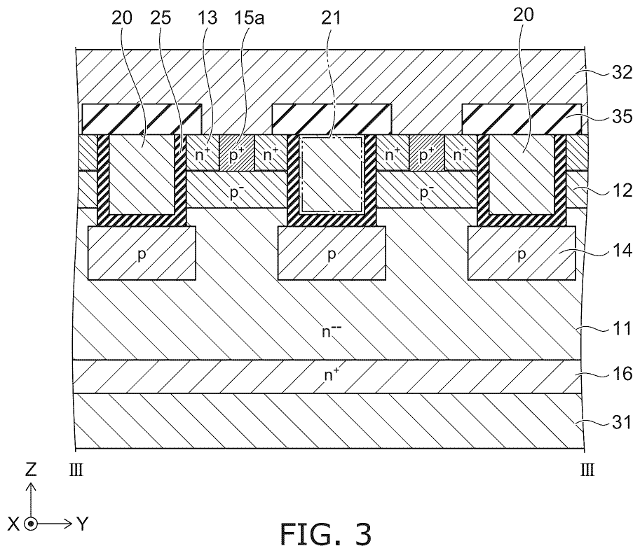

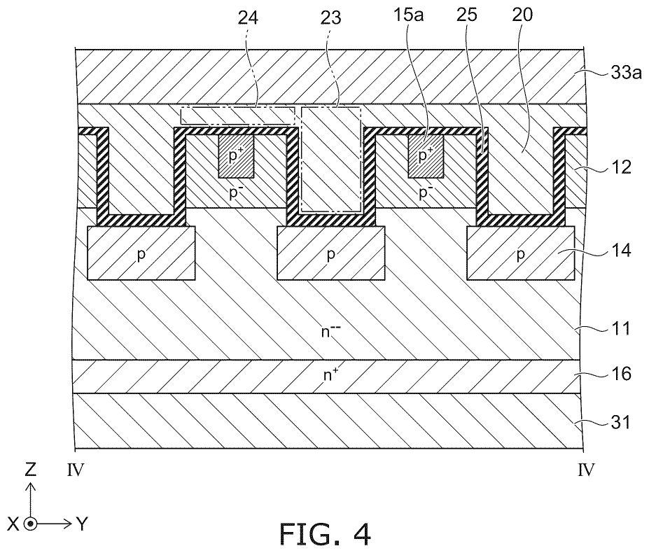

FIG. 1 is a plan view illustrating a semiconductor device according to an embodiment. FIG. 2 is an enlarged plan view of part II of FIG. 1. FIGS. 3 to 5 are, respectively, a III-III cross-sectional view, a IV-IV cross-sectional view, and a V-V cross-sectional view of FIG. 2.

The semiconductor device according to an embodiment is a Metal Oxide Semiconductor Field Effect Transistor (MOSFET). As shown in FIGS. 1 to 5, the semiconductor device 1 includes a semiconductor layer 10, a gate electrode 20, a first electrode 31, a second electrode 32, a third electrode 33, and an insulating layer 35.

An XYZ orthogonal coordinate system is used in the description of the embodiments. A direction from the first electrode 31 toward the semiconductor layer 10 is taken as a Z-direction (a first direction); and two mutually-orthogonal directions perpendicular to the Z-direction are taken as an X-direction (a third direction) and a Y-direction (a second direction). In the description, the direction from the first electrode 31 toward the semiconductor layer 10 is called “up/upward/higher than”, and the opposite direction is called “down/downward/lower than”. These directions are based on the relative positional relationship between the first electrode 31 and the semiconductor layer 10, and are independent of the direction of gravity.

As shown in FIG. 1, the second electrode 32 and the third electrode 33 are provided on the upper surface of the semiconductor device 1. The second electrode 32 and the third electrode 33 are separated from each other and electrically isolated. The third electrode 33 includes a wiring portion 33a extending along one direction and a pad portion 33b spreading along the X-Y plane. The wiring portion 33a is electrically connected to the pad portion 33b. A bonding wire or the like is connected to the pad portion 33b. The outer periphery of the semiconductor device 1 is covered by the insulating layer 35.

As shown in FIG. 2, the semiconductor layer 10, the gate electrode 20, and other elements are provided under the second electrode 32 and the third electrode 33. In FIG. 2, the insulating layer 35 is omitted, and the second electrode 32 and the wiring portion 33a are shown by dashed lines.

As shown in FIGS. 3 to 5, the first electrode 31 is provided on the lower surface of the semiconductor device 1. The semiconductor layer 10 is provided on the first electrode 31.

The semiconductor layer 10 includes an n⁻⁻ type (a first conductivity type) drift region 11 (a first semiconductor region), a p⁻-type (a second conductivity type) base region 12 (a second semiconductor region), an n⁺-type source region 13 (a third semiconductor region), a p-type shield region 14 (a fourth semiconductor region), a p⁺-type contact region 15a, a p⁺-type contact region 15b, and an n⁺-type drain region 16. The n⁺-type drain region 16 is provided on the first electrode 31 and is electrically connected to the first electrode 31. The n⁻⁻ type drift region 11 is provided on the n⁺-type drain region 16. The n-type impurity concentration in the n⁻⁻-type drift region 11 is lower than the n-type impurity concentration in the n⁺-type drain region 16.

The p⁻-type base region 12 is provided on the n⁻⁻-type drift region 11. The n⁺-type source region 13 and the p⁺-type contact region 15a are selectively provided on the p-type base region 12. The p-type impurity concentration in the p⁺-type contact region 15a is greater than the p-type impurity concentration in the p⁻-type base region 12.

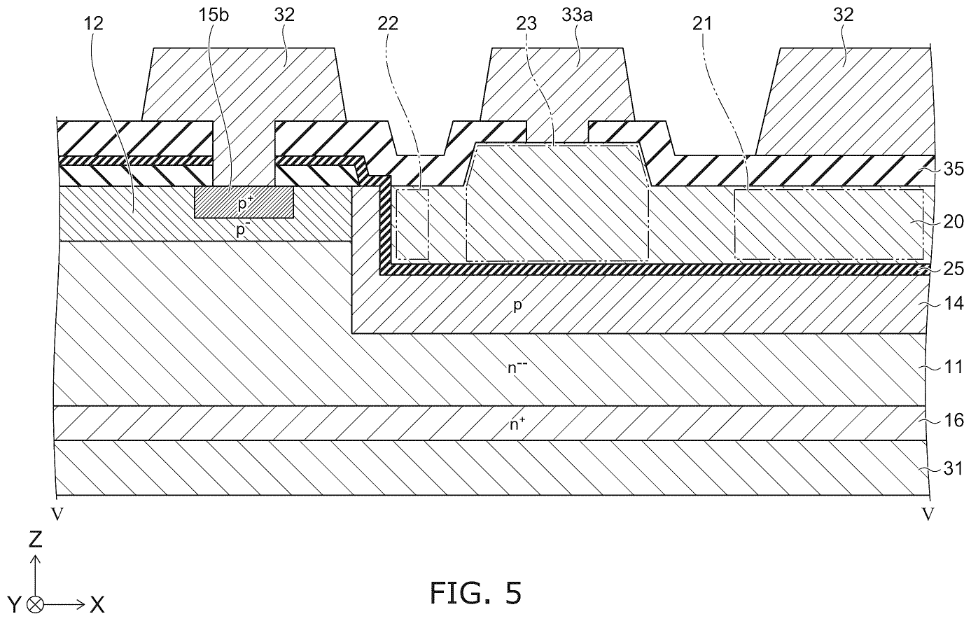

As shown in FIGS. 2 to 4, the gate electrode 20 faces the p⁻-type base region 12 via the gate insulating layer 25 in the Y-direction. The gate electrode 20 includes a first portion 21, a second portion 22, and a third portion 23. As shown in FIGS. 2 and 3, the first portion 21 is further facing the n⁺-type source region 13 via the gate insulating layer 25. As shown in FIGS. 2 and 5, the second portion 22 is positioned at an end of the gate electrode 20 in the X-direction and is separated from the first portion 21. The third portion 23 is positioned between the first portion 21 and the second portion 22 in the X-direction.

The gate electrode 20 is electrically conductive and contains polysilicon and impurities. The impurity contained in the gate electrode 20 may be n-type or p-type. In the gate electrode 20, the impurity concentration of the second portion 22 is less than the impurity concentration of the first portion 21 and less than the impurity concentration of the third portion 23.

The length of the first portion 21 in the X-direction is longer than the length in the X-direction of each of the second portion 22 and the third portion 23. For example, the length of the third portion 23 in the Z-direction is longer than the length in the Z-direction of each of the first portion 21 and the second portion 22.

As shown in FIGS. 2, 4, and 5, the wiring portion 33a is located on the third portion 23. The wiring portion 33a is in contact with the third portion 23, thereby the third electrode 33 is electrically connected to the gate electrode 20.

The p-type shield region 14 is provided between the n⁻⁻-type drift region 11 and the gate electrode 20 in the Z-direction, and is in contact with the gate insulating layer 25. The p-type impurity concentration in the p-type shield region 14 is greater than the p-type impurity concentration in the p⁻-type base region 12. For example, as shown in FIGS. 2 and 5, a part of the p-type shield region 14 faces the second portion 22 in the X-direction and is connected to the p-type base region 12. As shown in FIG. 3, the second electrode 32 is located on the n⁺-type source region 13 and the p⁺-type contact region 15a, and is electrically connected to the p-type base region 12, the n⁺-type source region 13, and the p⁺-type contact region 15a. The insulating layer 35 is provided between the gate electrode 20 and the second electrode 32, and the gate electrode 20 and the second electrode 32 are electrically isolated from each other.

As shown in FIG. 2, each of the p-type base region 12, n⁺-type source region 13, p⁺-type contact region 15a, and gate electrode 20 is provided in plurality in the Y-direction. Each of the p⁻-type base regions 12, n⁺-type source regions 13, p⁺-type contact regions 15a, and gate electrodes 20 extends in the X-direction. The wiring portion 33a extends over multiple third portions 23 in the Y-direction.

The p⁺-type contact region 15b is provided on the outer periphery of the p⁻-type base region 12 and is located around multiple p⁺-type contact regions 15a in the X-Y plane. The end of each p⁺-type contact region 15a in the X-direction is connected to the p⁺-type contact region 15b. A part of the second electrode 32 is provided on the p⁺-type contact region 15b, and the p⁺-type contact region 15b is electrically connected to the second electrode 32.

An example of a material for each component will now be described. The semiconductor layer 10 contains silicon carbide. As an n-type impurity, arsenic, phosphorus, or antimony can be used. As a p-type impurity, boron can be used. The gate electrode 20 is electrically conductive and contains polysilicon and impurities. The gate insulating layer 25 and the insulating layer 35 include an insulating material such as silicon oxide, silicon nitride, or silicon oxynitride. The first electrode 31, the second electrode 32, and the third electrode 33 include a metal such as aluminum.

The operation of the semiconductor device 1 will now be described. With a positive voltage applied to the first electrode 31 relative to the second electrode 32, a voltage exceeding the threshold value is applied to the gate electrode 20. As a result, a channel (an inversion layer) is formed in the p-type base region 12, and the semiconductor device 1 is turned on. Electrons flow from the second electrode 32 through the channel to the n⁻⁻-type drift region 11 and move toward the first electrode 31. As a result, a current flows through the semiconductor device 1. When the voltage applied to the gate electrode 20 falls below the threshold value, the channel in the p-type base region 12 disappears and the semiconductor device 1 is turned off.

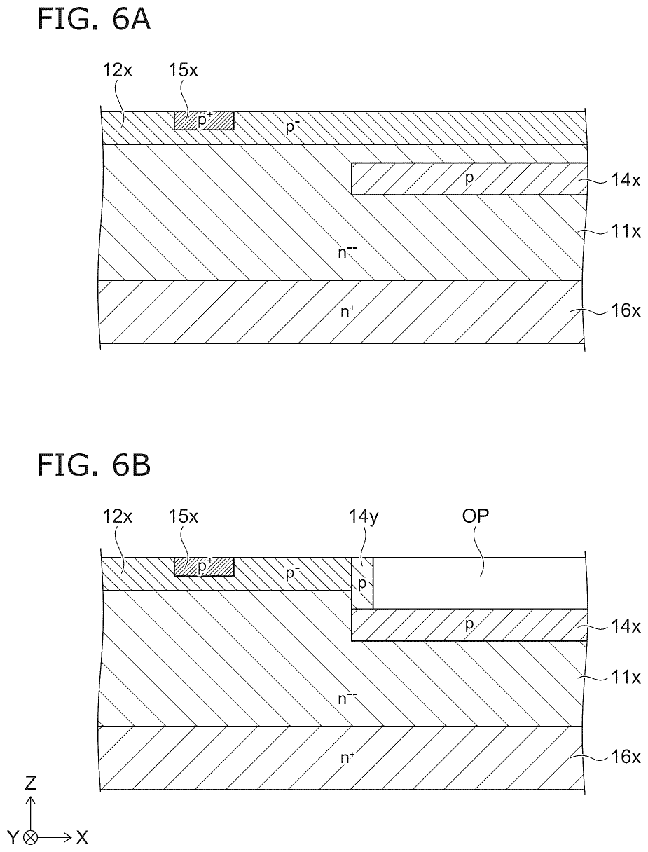

FIGS. 6A to 9B are cross-sectional views illustrating a manufacturing method for the semiconductor device according to the embodiment. FIGS. 6A to 9B show the manufacturing process in the V-V cross-section of FIG. 2.

First, a semiconductor substrate including the n⁺-type semiconductor layer 16x and the n⁻⁻-type semiconductor layer 11x is prepared. The n⁻⁻-type semiconductor layer 11x is provided on the n⁺-type semiconductor layer 16x. P-type impurities are ion-implanted into a predetermined region of the upper part of the n⁻⁻-type semiconductor layer 11x, and as shown in FIG. 6A, a p⁻-type semiconductor region 12x, a p-type semiconductor region 14x, and a p⁺-type semiconductor region 15x are formed. In addition, by sequentially ion-implanting n-type impurities and p-type impurities to the unillustrated region, the n⁺-type source region 13 and the p⁺-type contact region 15a, shown in FIGS. 2 and 3, are formed. The p⁺-type contact region 15a may be formed simultaneously with the p⁺-type semiconductor region 15x.

A part of the n⁻⁻-type semiconductor layer 11x and a part of the p-type semiconductor region 12x are removed to form an opening OP. At the bottom of the opening OP, the p-type semiconductor region 14x is located. Multiple openings OP are formed in the Y-direction, and each opening OP extends in the X-direction. P-type impurities are ion-implanted into the side surface of the opening OP in the X-direction to form a p-type semiconductor region 14y, as shown in FIG. 6B.

Thereafter, post-processing for the opening OP is performed. In the post-processing step, annealing in a hydrogen atmosphere or chemical dry etching (CDE) is performed. Through post-processing, the corners at the bottom of the opening OP are smoothed, and the curvature of the corners is reduced. Thereafter, the ion-implanted impurities are activated by a heat treatment.

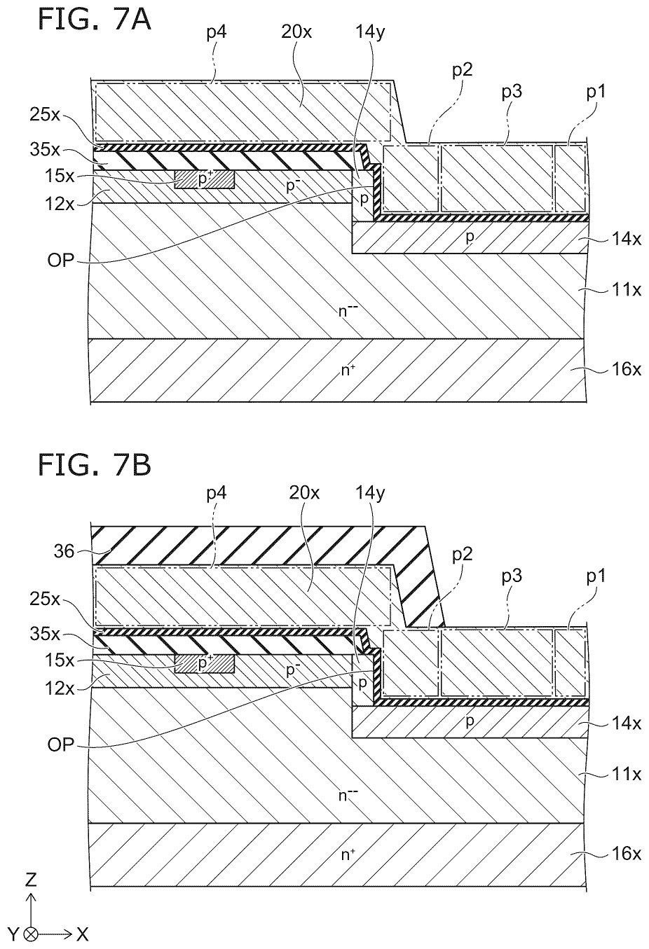

An insulating layer 35x is formed on the outer periphery of the p⁻-type semiconductor region 12x by Chemical Vapor Deposition (CVD). By CVD, an insulating layer 25x is formed along the inner surfaces of the openings OP and the surface of the insulating layer 35x. By CVD, polysilicon is deposited on the insulating layer 25x to form a conductive layer 20x. As shown in FIG. 7A, the openings OP are filled with the conductive layer 20x.

As shown in FIG. 7A, the conductive layer 20x includes a central portion p1, an end portion p2, an intermediate portion p3, and an outer peripheral portion p4. The central portion p1, the end portion p2, and the intermediate portion p3 are located inside the opening OP. The end portion p2 is positioned at the end of the opening OP in the X-direction. The intermediate portion p3 is positioned between the central portion p1 and the end portion p2. The outer peripheral portion p4 is positioned higher than the central portion p1, the end portion p2, and the intermediate portion p3, and is located on the outer periphery of the p-type semiconductor region 12x.

As shown in FIG. 7B, a protective film 36 covering the end portion p2 and the outer peripheral portion p4 is formed. The central portion p1 and the intermediate portion p3 are not covered with the protective film 36 and are exposed. The material of the protective film 36 can be appropriately selected, for example, silicon oxide or silicon nitride may be used.

With the end portion p2 and the outer peripheral portion p4 covered, impurities are diffused into the central portion p1 and the intermediate portion p3. As a specific example, impurities are diffused into the central portion p1 and the intermediate portion p3 of the conductive layer 20x by performing heat treatment in a gas atmosphere containing impurities. For example, a gas containing POC13 (phosphorus chloride) is used. A layer containing impurities may be formed on the conductive layer 20x and the protective film 36, and then the impurities may be diffused from the impurity-containing layer to the conductive layer 20x by performing heat treatment.

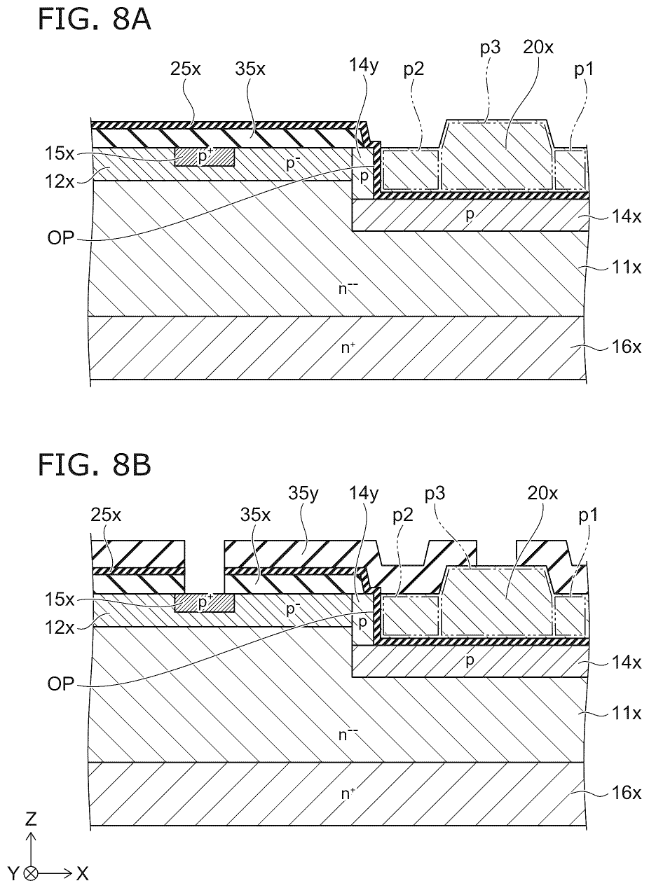

Impurities diffuse into the end portion p2 and the outer peripheral portion p4 through the central portion p1 and the intermediate portion p3. Therefore, the impurity concentration of each of the end portion p2 and the outer peripheral p4 is less than the impurity concentration of the central portion p1 and less than the impurity concentration of the intermediate portion p3. In the end portion p2, a gradient of impurity concentration is formed in the direction from the central portion p1 to the end portion p2. The protective film 36 is removed. The outer peripheral portion p4 is removed, and the upper surface of the central portion p1 and the upper surface of the end portion p2 are caused to be retreated. As a result, as shown in FIG. 8A, the upper surface of the intermediate portion p3 is positioned higher than the upper surface of the central portion p1 and the upper surface of the end portion p2.

An insulating layer 35y covering the conductive layer 20x and the insulating layer 25x is formed by CVD. A part of the insulating layer 35y is removed to expose the intermediate portion p3 and the p⁺-type semiconductor region 15x, as shown in FIG. 8B.

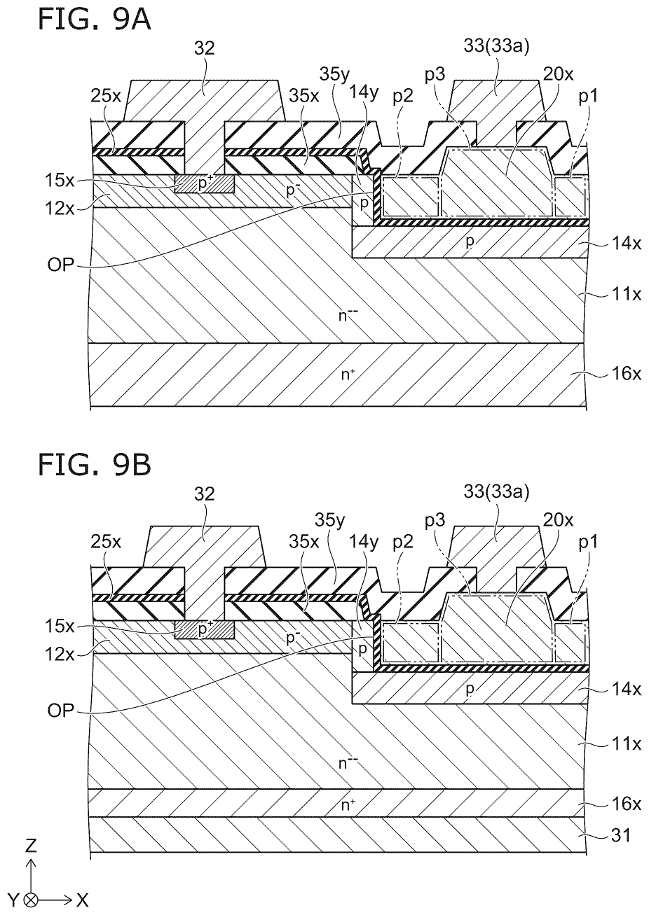

A metal layer is formed on the insulating layer 35y by sputtering. The metal layer is patterned to form the second electrode 32 and the third electrode 33, as shown in FIG. 9A. The back surface of the n⁺-type semiconductor layer 16x is ground until the n⁺-type semiconductor layer 16x reaches a predetermined thickness. As shown in FIG. 9B, the first electrode 31 is formed on the ground back surface by sputtering. Through the above steps, the semiconductor device 1 according to the embodiment is manufactured.

Advantages of the embodiment will now be described.

When the semiconductor device 1 is operated, a voltage is applied to the gate electrode 20. For example, a negative voltage may be applied to the first portion 21 and the second portion 22 of the gate electrode 20. At this time, the potential difference between the n⁻⁻-type drift region 11 and the gate electrode 20 increases, and the electric field strength in the vicinity of the gate electrode 20 increases. In particular, the electric field strength in the vicinity of the second portion 22, which is located at the end of the gate electrode 20, tends to be greater than that in the other portions. When an electric field concentration occurs in the vicinity of the second portion 22, dielectric breakdown of the gate insulating layer 25 occurs. The first electrode 31 and the third electrode 33 become electrically connected, causing the semiconductor device 1 to break down.

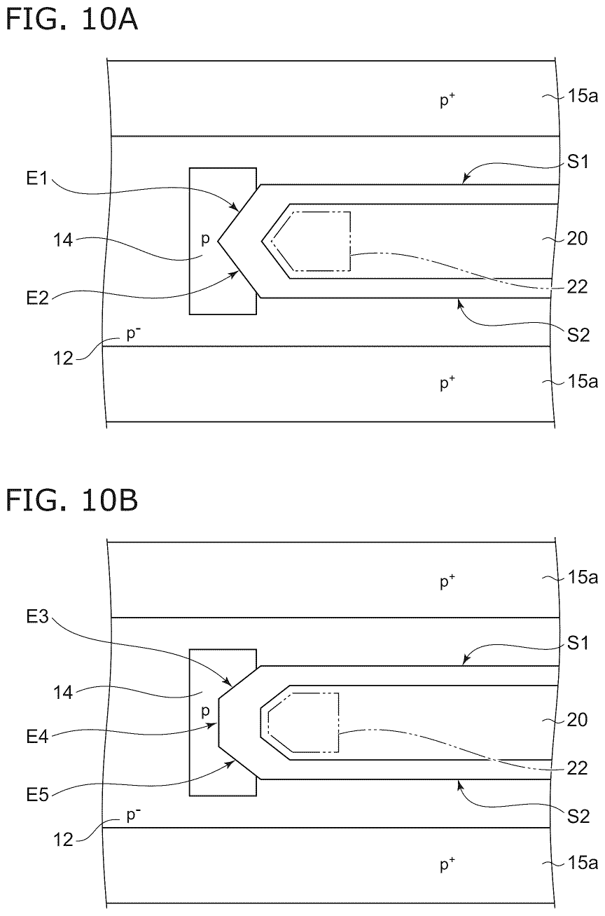

FIGS. 10A and 10B are plan views illustrating the second portion of the gate electrode.

In particular, when the semiconductor layer 10 contains silicon carbide, breakdown is more likely to occur in the vicinity of the second portion 22 for the following reasons. As described in the manufacturing method, after the formation of the opening OP, post-processing of the opening OP is performed. Through post-processing, the curvature of the corners at the bottom of the opening OP is reduced. Therefore, the curvature of the corners at the bottom of the gate electrode 20, which is formed thereafter, can be reduced. As a result, when a voltage is applied to the gate electrode 20, the occurrence of electric field concentration at the corner of the bottom of the gate electrode 20 can be suppressed.

On the other hand, when the semiconductor layer 10 contains silicon carbide, through post-processing, a surface parallel to the plane orientation of silicon carbide appears at the end of the opening OP in the X-direction. As a result, the gate electrode 20 and the gate insulating layer 25 also have surfaces parallel to the plane orientation of silicon carbide. In the example of FIG. 10A, the gate insulating layer 25 has a side surface S1, a side surface S2, an end surface E1, and an end surface E2. The side surfaces S1 and S2 are parallel to the X-Z plane. The end surfaces E1 and E2 are inclined with respect to the X-Z plane. In the example of FIG. 10B, the gate insulating layer 25 has the side surface S1, the side surface S2, and end surfaces E3 to E5. The end surfaces E3 and E5 are inclined with respect to the X-Z plane. The end surface E4 is parallel to the Y-Z plane. The end surfaces E1 to E5 are substantially parallel to the crystal planes of silicon carbide. When the end surfaces E1 to E5 appear, the curvature of the corners between these surfaces increases. As a result, electric field concentration is more likely to occur in the vicinity of the second portion 22.

In the semiconductor device 1 according to the embodiment, the impurity concentration of the second portion 22 is lower than the impurity concentration of the third portion 23. Therefore, the electrical resistivity of the second portion 22 is greater than the electrical resistivity of the third portion 23. When a voltage is applied to the gate electrode 20, the current flowing through the second portion 22 is smaller than the current flowing through the first portion 21 and the third portion 23. The voltage of the second portion 22 can be less than the voltage of each of the first portion 21 and the third portion 23. Therefore, the electric field strength in the vicinity of the second portion 22 can be reduced. As a result, the gate insulating layer 25 is less likely to undergo dielectric breakdown, and the occurrence of breakdown in the semiconductor device 1 can be suppressed.

Additionally, the wiring portion 33a is connected to the third portion 23, which is distinct from the second portion 22. The impurity concentration of the third portion 23 is greater than the impurity concentration of the second portion 22. Therefore, even when the impurity concentration of the second portion 22 is reduced, an increase in electrical resistance between the gate electrode 20 and the wiring portion 33a can be suppressed.

According to the embodiment, the occurrence of breakdown in the semiconductor device 1 can be suppressed while suppressing an increase in the electrical resistance of the gate electrode 20.

The impurity concentration of the second portion 22 is preferably less than 0.5 times the impurity concentration of the third portion 23. As a result, compared to the first portion 21 and the third portion 23, the increase in the voltage of the second portion 22 can be effectively suppressed, and the electric field strength in the vicinity of the second portion 22 can be sufficiently reduced. More preferably, the impurity concentration of the second portion 22 is greater than 0.001 times and less than 0.1 times the impurity concentration of the third portion 23.

The gate electrode 20 preferably contains phosphorus. By using phosphorus, the electrical resistance of the gate electrode 20 can be reduced compared to the case where other impurities are used, and the threshold voltage can be lowered.

The semiconductor layer 10 preferably includes a p-type shield region 14. The p-type shield region 14 is provided between the n^{31 -}-type drift region 11 and the gate electrode 20. By providing the p-type shield region 14, the electric field strength in the vicinity of the bottom of the gate electrode 20 can be relaxed. Therefore, the occurrence of dielectric breakdown of the gate insulating layer 25 can be further suppressed. In particular, when the p-type shield region 14 faces at least a part of the second portion 22 via the gate insulating layer 25, the electric field strength in the vicinity of the second portion 22 can be further reduced.

### First Modification

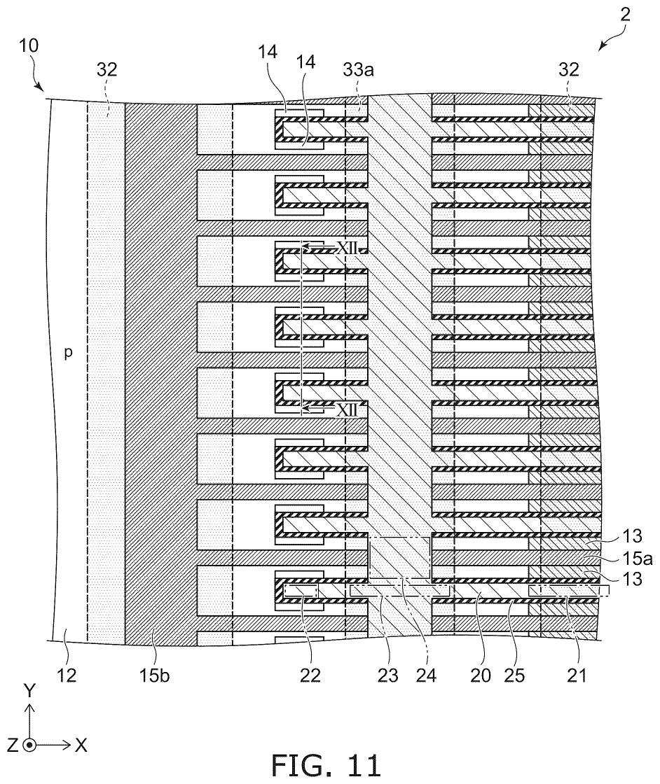

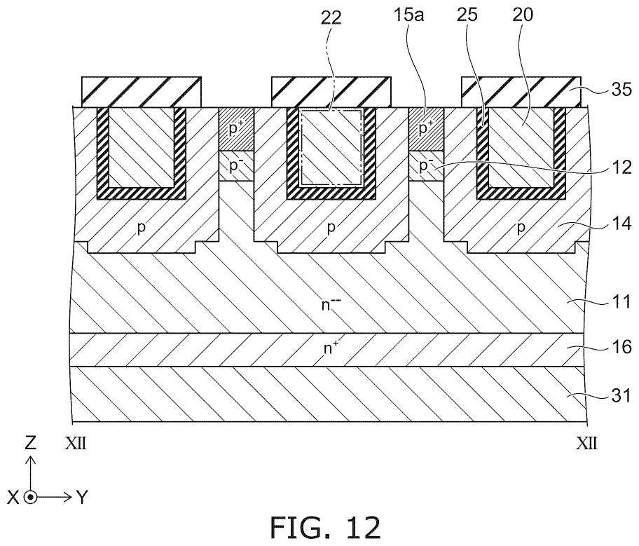

FIG. 11 is a plan view illustrating a part of a semiconductor device according to a first modification of the embodiment. FIG. 12 is a XII-XII cross-sectional view of FIG. 11. In FIG. 11, the insulating layer 35 is omitted, and the second electrode 32 and the wiring portion 33a are shown by dashed lines.

In the semiconductor device 2 according to the first modification, a part of the p-type shield region 14 faces the second portion 22 via the gate insulating layer 25 in the Y-direction, as shown in FIGS. 11 and 12. This part of the p-type shield region 14 is connected to the p-type base region 12. A part of the p-type shield region 14 may also face the third portion 23.

In the illustrated example, the p-type shield region 14 is provided on both sides of the second portion 22 in the Y-direction. Alternatively, the p-type shield region 14 may be provided only on one side of the second portion 22 in the Y-direction. The arrangement of the portion of the p-type shield region 14 connected to the p-type base region 12 can be appropriately changed.

### Second Modification

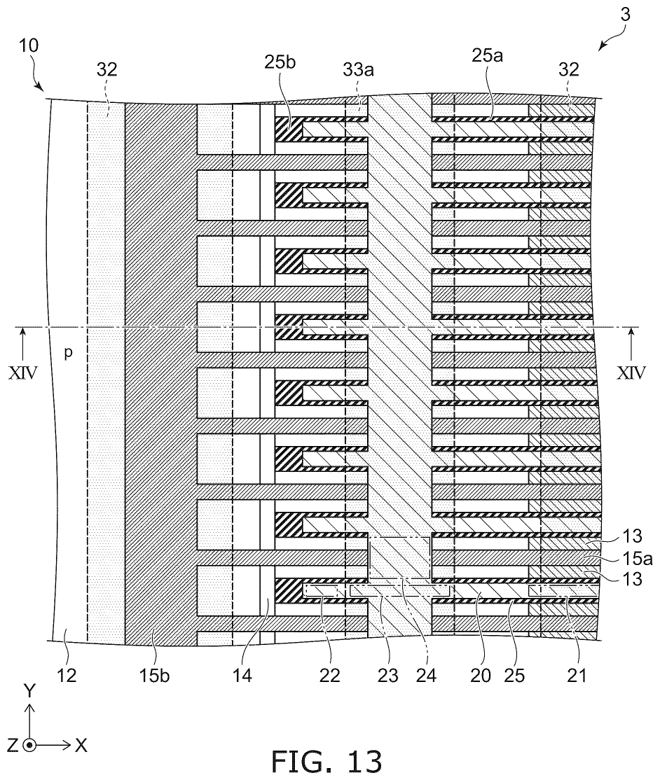

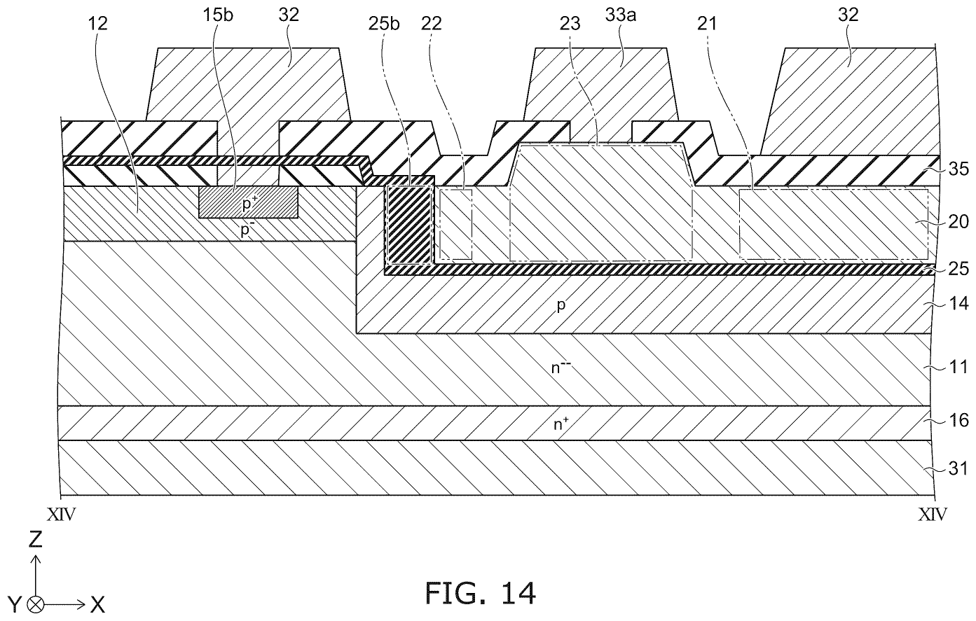

FIG. 13 is a plan view illustrating a part of a semiconductor device according to a second modification of the embodiment. FIG. 14 is a XIV-XIV cross-sectional view of FIG. 13. In FIG. 13, the insulating layer 35 is omitted, and the second electrode 32 and the wiring portion 33a are shown by dashed lines.

In the semiconductor device 3 according to the second modification, the gate insulating layer 25 includes a first insulating region 25a and a second insulating region 25b, as shown in FIGS. 13 and 14.

The first insulating region 25a is provided between the semiconductor layer 10 and the gate electrode 20 in the Y-direction. The first insulating region 25a is in contact with the first portion 21, the second portion 22, and the third portion 23 in the Y-direction. The second insulating region 25b is provided between the semiconductor layer 10 and the gate electrode 20 in the X-direction.

The second insulating region 25b is in contact with the second portion 22 in the X-direction.

The thickness of the second insulating region 25b is greater than the thickness of the first insulating region 25a. The thickness of the first insulating region 25a corresponds to the distance between the semiconductor layer 10 and the gate electrode 20 in the Y-direction. The thickness of the second insulating region 25b corresponds to the distance between the semiconductor layer 10 and the gate electrode 20 in the X-direction.

After forming the opening OP as shown in FIG. 6B, an insulating layer is formed only at the ends of the opening OP in the Y-direction. Thereafter, the same method as that in FIG. 7A and subsequent steps is performed. This allows the formation of the gate insulating layer 25, which includes the second insulating region 25b that is thicker than the other portions.

When the gate insulating layer 25 includes the second insulating region 25b, the electric field strength in the vicinity of the second portion 22 can be further reduced. According to the second modification, the occurrence of breakdown in the semiconductor device 3 can be further suppressed compared to that in the semiconductor device 1.

The embodiment of the present invention may include the following configurations.

### (Configuration 1)

A semiconductor device comprising:

a first electrode;

a semiconductor layer containing silicon carbide, the semiconductor layer including
a first semiconductor region of a first conductivity type provided on the first electrode,
a second semiconductor region of a second conductivity type provided on the first semiconductor region, and
a third semiconductor region of the first conductivity type provided on the second semiconductor region;

a second electrode provided on the second semiconductor region and the third semiconductor region;

a gate electrode facing the second semiconductor region via a gate insulating layer in a second direction, the second direction being perpendicular to a first direction from the first electrode toward the first semiconductor region, the gate electrode including
a first portion further facing the third semiconductor region,
a second portion positioned at an end of the gate electrode in a third direction, the third direction being perpendicular to the first direction and the second direction, and
a third portion positioned between the first portion and the second portion in the third direction, the impurity concentration of the second portion being less than the impurity concentration of the third portion; and

a third electrode separated from the second electrode and electrically connected to the gate electrode, the third electrode including a wiring portion provided on the third portion.

### (Configuration 2)

The semiconductor device according to configuration 1, wherein

the semiconductor layer further includes a fourth semiconductor region of the second conductivity type provided between the first semiconductor region and the gate electrode, and the fourth semiconductor region is connected to the second semiconductor region.

### (Configuration 3)

The semiconductor device according to configuration 2, wherein

a part of the fourth semiconductor region faces the third portion via the gate insulating layer in the second direction or the third direction.

### (Configuration 4)

The semiconductor device according to any one of configurations 1 to 3, wherein

the impurity concentration of the second portion is less than 0.5 times the impurity concentration of the third portion. (Configuration 5)

The semiconductor device according to any one of configurations 1 to 4, wherein

the gate electrode is provided in plurality in the second direction; and

the wiring portion is located on a plurality of the third portions.

### (Configuration 6)

The semiconductor device according to any one of configurations 1 to 5, wherein

the gate insulating layer includes
a first insulating region provided between the gate electrode and the semiconductor layer in the second direction, and
a second insulating region provided between the gate electrode and the semiconductor layer in the third direction, and

the thickness of the second insulating region is greater than the thickness of the first insulating region.

### (Configuration 7)

The semiconductor device according to any one of configurations 1 to 6, wherein

the length of the third portion in the first direction is greater than the length of the first portion in the second direction and greater than the length of the second portion in the second direction.

According to the embodiment described above, the occurrence of breakdown in the semiconductor device can be suppressed while suppressing the increase in the electrical resistance of the gate electrode.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device comprising:
a first electrode;
a semiconductor layer containing silicon carbide, the semiconductor layer including
a first semiconductor region of a first conductivity type provided on the first electrode,
a second semiconductor region of a second conductivity type provided on the first semiconductor region, and
a third semiconductor region of the first conductivity type provided on the second semiconductor region;
a second electrode provided on the second semiconductor region and the third semiconductor region;
a gate electrode facing the second semiconductor region via a gate insulating layer in a second direction, the second direction being perpendicular to a first direction from the first electrode toward the first semiconductor region, the gate electrode including
a first portion further facing the third semiconductor region,
a second portion positioned at an end of the gate electrode in a third direction, the third direction being perpendicular to the first direction and the second direction, and
a third portion positioned between the first portion and the second portion in the third direction, the impurity concentration of the second portion being less than the impurity concentration of the third portion; and
a third electrode separated from the second electrode and electrically connected to the gate electrode, the third electrode including a wiring portion provided on the third portion.

2. The semiconductor device according to claim 1, wherein
the semiconductor layer further includes a fourth semiconductor region of the second conductivity type provided between the first semiconductor region and the gate electrode, and
the fourth semiconductor region is connected to the second semiconductor region.

3. The semiconductor device according to claim 2, wherein
a part of the fourth semiconductor region faces the third portion via the gate insulating layer in the second direction or the third direction.

4. The semiconductor device according to claim 1, wherein
the impurity concentration of the second portion is less than 0.5 times the impurity concentration of the third portion.

5. The semiconductor device according to claim 1, wherein
the gate electrode is provided in plurality in the second direction; and
the wiring portion is located on a plurality of the third portions.

6. The semiconductor device according to claim 1, wherein
the gate insulating layer includes
a first insulating region provided between the gate electrode and the semiconductor layer in the second direction, and
a second insulating region provided between the gate electrode and the semiconductor layer in the third direction, and
the thickness of the second insulating region is greater than the thickness of the first insulating region.

7. The semiconductor device according to claim 1, wherein
the length of the third portion in the first direction is greater than the length of the first portion in the second direction and greater than the length of the second portion in the second direction.
